(19) United States
(12) Patent Application Publication
(10) Pub. No.: US 2015/0068907 A1
(43) Pub. Date: Mar. 12, 2015

(54) LAMINATE, CONDUCTIVE PATTERN, ELECTRIC CIRCUIT, AND METHOD FOR PRODUCING LAMINATE

(71) Applicant: DIC Corporation, Tokyo (JP)

(72) Inventors: Wataru Fujikawa, Osaka (JP); Yukie Saitou, Osaka (JP); Akira Murakawa, Osaka (JP); Jun Shirakami, Osaka (JP)

(73) Assignee: DIC Corporation, Tokyo (JP)

(21) Appl. No.: 14/389,688

(22) PCT Filed: Mar. 28, 2013
(86) PCT No.: PCT/JP2013/059318

§ 371 Date: Sep. 30, 2014

(30) Foreign Application Priority Data
Mar. 30, 2012 (JP) 2012-080358

(51) Int. Cl. H05K 1/02; H05K 3/02; C25D 3/02; H05K 3/38; H05K 1/09; H05K 3/18

(52) U.S. Cl. CPC H05K 1/0296; H05K 1/092; H05K 3/188; C25D 3/02; H05K 3/385; H05K 3/022
USPC 205/50; 174/255; 205/159

(57) ABSTRACT

It is an object of the present invention to provide a laminate, such as a conductive pattern, having an excellent adhesion at the interfaces between a layer that serves as a support and a conductive layer containing a conductive material and between the conductive layer and a plating layer. The present invention provides a laminate at least including a support layer (I), a conductive layer (II) having an oxidized surface, and a plating layer (III) formed on the oxidized surface of the conductive layer (II); the present invention also provides a conductive pattern and electric circuit each including such a laminate.

### TECHNICAL FIELD

The present invention relates to a laminate, such as a conductive pattern, which can be used for producing, for example, electromagnetic interference shields, integral circuits, and organic transistors.

### BACKGROUND ART

In recent years, an improvement in the performance of electronic devices and reductions in the size and thickness thereof have generated strong demands for enhancing the density of electronic circuits and integrated circuits used therein and for reducing the size and thickness of these circuits.

In an example of known conductive patterns which can be used in such electronic circuits or other circuits, a conductive ink or nucleating agent for plating, which contains a conductive material such as silver, is applied to the surface of a support and then fired to form a layer of the conductive material, and then the surface of the layer of the conductive material is plated to form a plating layer on the surface of the layer of the conductive material (for instance, see Patent Literatures 1 and 2).

Such a conductive pattern, however, has an insufficient adhesion at the interface between the layer of the conductive material and the plating layer, and the plating layer therefore peels off over time, which results in reduced conductivity (increased resistance) or disconnection in some cases.

A technique for enhancing the adhesion between the layer of the conductive material and the plating layer has been studied; for example, the surface of the layer of the conductive material is irradiated with ultraviolet light, and then this surface is plated.

In a conductive pattern formed through the irradiation with ultraviolet light, however, the adhesion has been reduced at the interface between the support and the layer of the conductive material, which leads to reduced conductivity (increased resistance) or disconnection in some cases.

A laminate such as a conductive pattern needs to have a good adhesion at the interfaces between the support and the conductive layer and between the conductive layer and the plating layer; however, a laminate which can completely satisfy such a requirement has not been developed yet.

### CITATION LIST

### Patent Literature

PTL 1: Japanese Unexamined Patent Application Publication No. 60-246695

PTL 2: Japanese Unexamined Patent Application Publication No. 2005-286158

### SUMMARY OF INVENTION

### Technical Problem

It is an object of the present invention to provide a laminate, such as a conductive pattern, having an excellent adhesion at the interfaces between a layer that serves as a support and a conductive layer containing a conductive material and between the conductive layer and a plating layer.

### Solution to Problem

The inventors have studied for the above-mentioned object and found that the object can be achieved by preliminarily oxidizing the surface of the conductive layer and forming the plating layer on the oxidized surface.

In particular, the present invention provides a laminate at least including a support layer (I), a conductive layer (II), and a plating layer (III), wherein the conductive layer (II) has an oxidized surface, and the plating layer (III) is disposed on the oxidized surface of the conductive layer (II); the present invention also provides a conductive pattern and an electric circuit each including such a laminate.

### Advantageous Effects of Invention

The laminate of the present invention includes the support layer, the conductive layer, and the plating layer with excellent adhesion between the layers and has an excellent conductivity. Hence, the laminate can be used in a new technical field generally called printed electronics such as formation of conductive patterns; formation of peripheral wiring used in electronic circuits, organic solar cells, terminals for electronic books, organic EL devices, organic transistors, flexible printed wiring boards, and RFID, e.g., a contactless IC card; formation of wiring of electromagnetic interference shields used in plasma displays; and production of integrated circuits and organic transistors.

### DESCRIPTION OF EMBODIMENTS

The laminate of the present invention at least includes a support layer (I), a conductive layer (II), and a plating layer (III); the conductive layer (II) has an oxidized surface; and the plating layer (III) is formed on the oxidized surface of the conductive layer (II). The laminate can be desirably applied to, for example, a conductive pattern and an electric circuit.

The support layer (I) included in the laminate of the present invention will now be described.

The support layer (I) included in the laminate of the present invention is a layer that serves as a support for supporting the laminate. The support layer (I) can be formed of a material which will be described later as a material usable as the support; a resin layer is preferred.

The thickness of the support layer (I) is preferably in the range of approximately 1 μm to 5,000 μm, and more preferably approximately 1 μm to 300 μm. In the case where the laminate needs to be relatively flexible, the thickness is preferably in the range of approximately 1 μm to 200 μm. The thickness of the support layer (I) can be adjusted by changing a support to be used.

The conductive layer (II) included in the laminate of the present invention will now be described.

The conductive layer (II) mainly contains a conductive material.

An example of the conductive layer (II) is a layer containing a transition metal or a compound thereof as the conductive material. In particular, a layer containing an ionic transition metal is preferred; a layer containing a transition metal, such as copper, silver, gold, nickel, palladium, platinum, or cobalt, is more preferred; and a layer containing copper, silver, or gold is further preferred to form a laminate, such as a conductive pattern, having a low electric resistance and a good corrosion resistance.

The conductive material used in the conductive layer (II) is preferably contained in a fluid such as a conductive ink or a nucleating agent for plating. Although the conductive layer (II) mainly contains the conductive material as described above, a solvent, additive, and another material which are contained in the fluid may remain in the conductive layer (II).

In the laminate of the present invention, not only the support layer (I), the conductive layer (II), and the plating layer (III) are merely laminated; but also part or the whole of the surface of the conductive layer (II) which is in contact with the plating layer (III) is oxidized.

The term oxidization herein refers to formation of oxide by combining the conductive material contained in the conductive layer (II) with oxygen and comprehends the case in which the valency of the conductive material increases.

For example, in the case where the conductive material contained in the conductive layer (II) is silver, the oxidized surface of the conductive layer (II) can be a surface formed of silver oxide or a surface formed of a substance which has been generated by combining the silver with, for instance, a hydroxyl group with an increase in its valency from 0 to +1.

In the conductive layer (II), part of the surface which is in contact with the plating layer (III) can be oxidized, and the other part thereof which is not in contact with the plating layer (II) is preferably not oxidized.

The resistance of the oxidized surface of the conductive layer (II) is preferably in the range of 0.1Ω/□ to 50Ω/□, and more preferably 0.2Ω/□ to 30Ω/□ to produce good adhesion to the plating layer (III).

The conductive layer (II) may be directly disposed on at least one of the surfaces of the support layer (I); however, the conductive layer (II) is preferably disposed above at least one of the surfaces of the support layer (I) with a primer layer (X), which will be described later, interposed therebetween in order to produce a laminate in which the adhesion has been further enhanced.

The conductive layer (II) may be disposed on at least part of the support layer (I) or primer layer (X) or may be disposed on one or both of the surfaces thereof. In the laminate, for example, the conductive layer (II) may be disposed on the whole of the support layer (I) or primer layer (X) or may be disposed only at the intended part of the surfaces of the support layer (I) or primer layer (X). An example of the conductive layer (II) disposed only at the intended part of the surfaces of the support layer (I) or primer layer (X) is a linear layer formed by applying a material in the form of a line. A laminate having a linear layer as the conductive layer (II) is suitable for production of, for instance, a conductive pattern or electric circuit.

The width of the linear layer (line width) is in the range of approximately 0.01 μm to 200 μm, and preferably approximately 0.01 μm to 150 μm in order to, for example, enhance the density of a conductive pattern.

The thickness of the conductive layer (II) included in the laminate of the present invention can be in the range of 10 nm to 10 μm. The thickness of the conductive layer (II) is preferably in the range of 10 nm to 1 μm because the adhesion between the conductive layer (II) and the plating layer (III) can be further enhanced; the thickness is more preferably in the range of 10 nm to 300 nm because the adhesion can be even further enhanced. The thickness of the conductive layer (II) can be adjusted by controlling, for instance, the amount of a conductive material-containing fluid which can be used for forming the conductive layer (II). In the case where the conductive layer (II) is in the form of a thin line, the thickness (height) is preferably in the range of 10 nm to 1 μm.

The plating layer (III) included in the laminate of the present invention is provided to form a highly reliable wiring pattern which can maintain the good flow of electricity for a long time without the occurrence of disconnection or another problem in the case where the laminate is used as, for instance, a conductive pattern.

The plating layer (III) is, for example, preferably a layer formed of a metal, such as copper, nickel, chromium, cobalt, or tin, and more preferably a plating layer formed of copper.

The thickness of the plating layer (III) can be in the range of 1 μm to 50 μm. The thickness of the plating layer (III) can be adjusted by controlling, for instance, a processing time, current density, or the amount of an additive for plating in a plating process for forming the plating layer (III).

The laminate of the present invention preferably includes the primer layer (X) disposed between the support layer (I) and the conductive layer (II) in order to further enhance the adhesion between the support layer (I) and the conductive layer (II); in the case where the conductive layer (II) is in the form of a linear layer (e.g., wiring pattern), the primer layer (X) also enables a decrease in the width of the linear layer.

According to the technique of the present invention, the conductive layer (II) has an oxidized surface, and the plating layer is formed on the oxidized surface; hence, the laminate in which the support layer (I), the primer layer (X), the conductive layer (II), and the plating layer (III) have adhered to each other in a good manner can be produced without degradation of the primer layer (X) or another problem.

The primer layer (X) may be disposed on part or the whole of a surface of the support layer (I) or may be disposed on one or both of the surfaces thereof. In an example of the usable laminate, the primer layer (X) is disposed entirely on a surface of the support layer (I), and the conductive layer (II) is disposed only at the intended part of the primer layer (X). In another example of the usable laminate, the primer layer (X) is disposed only at part of a surface of the support layer (I) so as to correspond to the position of the conductive layer (II) to be formed.

The thickness of the primer layer (X) depends on, for example, applications of the laminate of the present invention; in order to further enhance the adhesion between the support layer (I) and the conductive layer (II), the thickness is preferably approximately in the range of 10 nm to 300 μm, and more preferably 10 nm to 500 nm.

A method for producing the laminate of the present invention will now be described.

The laminate of the present invention can be produced, for example, through a process [1] and a process [2]; in the process [1], a fluid containing a conductive material is applied to part or the whole of the surface of a support that serves as the support layer (I) and fired to form a layer (II′) containing the conductive material; in the process [2], part or the whole of the surface of the layer (II′) containing the conductive material is oxidized, and then the oxidized surface is plated to form the plating layer (III) on the oxidized surface of the conductive layer (II).

The process [1] will now be described.

In the process [1], a fluid containing a conductive material is applied to part or the whole of the surface of a support and fired to form the layer (II′) containing the conductive material. The fluid may be applied directly to the surface of the support. The fluid also may be applied to part or the whole of the surface of the primer layer (X) optionally formed on the surface of the support.

In order to enhance the adhesion to the primer layer (X), the surface of the support layer (I) may be subjected to, for example, a surface treatment for formation of fine irregularities; removal of dirt remaining on the surface; or introduction of a functional group such as a hydroxyl group, a carbonyl group, or a carboxyl group. In particular, a plasma discharge treatment such as a corona discharge treatment; a dry treatment such as an ultraviolet treatment; or a wet treatment with water, an aqueous solution such as an acid or alkaline solution, or an organic solvent may be carried out.

Examples of a technique for applying the fluid to the surface of the support (surface of the support layer (I)) include ink-jet printing, reverse printing, screen printing, offset printing, spin coating, spray coating, bar coating, die coating, slit coating, roll coating, and dip coating.

The fluid is preferably applied by ink-jet printing or reverse printing in the case where the fluid is used to form the conductive material-containing layer (II′) that is in the form of a thin line having a width of approximately 0.01 μm to 100 μm which is needed to enhance the density of, for instance, an electric circuit.

In the ink-jet printing, an apparatus generally called ink-jet printer can be used. Specific examples of the ink-jet printer include KONICA MINOLTA EB100 and XY100 (manufactured by Konica Minolta IJ Technologies, Inc.) and Dimatix Material Printer DMP-3000 and DMP-2831 (manufactured by FUJIFILM Corporation).

Examples of known reverse printing include reverse printing with a letterpress and reverse printing with an intaglio; for instance, the fluid is applied to the surface of any of a variety of blankets, the blanket is brought into contact with a plate having a protrusion, which serves as a non-image part, to form a pattern on the surface of the blanket by selectively transferring part of the fluid corresponding to the non-image part to the surface of the plate, and then the pattern is transferred to the surface of the support layer (I) or the surface of the primer layer (X).

After the application of the fluid, the firing is carried out to allow particles of the conductive material, such as metal, contained in the fluid to cohere with each other, thereby forming the layer (II′) having a conductivity. The firing is preferably carried out at a temperature approximately ranging from 80° C. to 300° C. for around 2 minutes to 200 minutes. The firing may be carried out in the atmosphere; in order to prevent oxidation of the whole conductive material such as metal, part or all of the firing procedure may be carried out in a reducing atmosphere.

The firing can be carried out by a technique which involves, for instance, an oven, a hot-air drying oven, an infrared dryer, laser radiation, or microwave.

Examples of the support used in the process [1] include supports and porous supports formed of a polyimide resin, a polyamide-imide resin, a polyamide resin, polyethylene terephthalate, polyethylene naphthalate, polycarbonate, acrylonitrile-butadiene-styrene (ABS), an acrylic resin such as polymethyl (meth)acrylate, polyvinylidene fluoride, polyvinyl chloride, polyvinylidene chloride, polyvinyl alcohol, polyethylene, polypropylene, polyurethane, cellulose nanofiber, silicon, ceramics, glass, glass epoxy, glass polyimide, and paper phenol.

The support also can be a substrate formed of, for example, synthetic fiber, such as polyester fiber, polyamide fiber, or aramid fiber, or natural fiber such as cotton or hemp. Such fiber may be processed in advance.

The support is preferably a support which is generally used for forming conductive patterns of, for instance, circuit boards in many cases, and such a support is formed of a polyimide resin, polyethylene terephthalate, polyethylene naphthalate, glass, a glass epoxy resin, a glass polyimide resin, paper phenol, a cellulose nanofiber, an alumina substrate, a mullite substrate, a steatite substrate, a forsterite substrate, or a zirconia substrate.

In the case where the laminate such as a conductive pattern according to the present invention needs to have a flexibility on its use, a relatively flexible support which can be bent is preferably employed as the above-mentioned support to impart flexibility to the conductive pattern, so that a bendable final product can be produced. In particular, a film or sheet-like support which is formed by, for example, uniaxial stretching is preferably used.

Preferred examples of the film or sheet-like support include a polyethylene terephthalate film, a polyimide film, and a polyethylene naphthalate film.

The thickness of the support is preferably in the range of approximately 1 μm to 5,000 μm, and more preferably 1 μm to 300 μm to reduce the weight and thickness of a conductive pattern and final product in which the conductive pattern is used. In the case where the laminate needs to be relatively flexible, the thickness of the support is preferably from approximately 1 μm to 200 μm.

The fluid used for forming the conductive material-containing layer (II′) in the process [1] can be a fluid containing a conductive material for forming the layer (II′) and optionally a solvent and an additive, and a material generally known as a conductive ink or a nucleating agent for plating can be employed.

Examples of a usable conductive material include transition metals and compounds thereof. In particular, ionic transition metals are preferably employed; transition metals, such as copper, silver, gold, nickel, palladium, platinum, and cobalt, are preferred; copper, silver, and gold are more preferred because use of such transition metals enables formation of a conductive pattern having a low electric resistance and a high corrosion resistance; and silver is further preferred.

In the case where a nucleating agent for plating is used as the fluid, the conductive material can be at least one selected from metal particles of the above-mentioned transition metals and materials produced by coating such metal particles with oxides or organic substances of the above-mentioned transition metals.

Since the above-mentioned transition metal oxides are normally inactive (insulated), merely applying a fluid containing any of such oxides to the surface of the support does not produce conductivity in many cases. Hence, in the case where the fluid containing any of the above-mentioned oxides is applied to the surface of the support, this surface is treated with a reducing agent, such as dimethylaminoborane, to expose the transition metal, thereby being able to form the conductive layer (II) which is active (having conductivity).

Examples of the above-mentioned metal coated with the organic substance include metals encapsulated in resin particles (organic substances) by emulsion polymerization. Such particles are normally inactive (insulated) as in the above-mentioned transition metal oxides, and merely applying a fluid containing the particles to the surface of the support therefore does not produce conductivity in many cases. Hence, in the case where a fluid containing the above-mentioned metal coated with the organic substance is applied to the surface of the support, this surface is irradiated with, for example, laser light to remove the organic substance, so that the transition metal can be exposed to form the conductive layer (II) which is active (having conductivity).

The conductive material is preferably in the form of particles having an average particle size ranging from approximately 1 nm to 100 nm, and more preferably particles having an average particle size ranging from 1 nm to 50 nm because a fine conductive pattern can be formed and a resistance after the sintering can be further decreased as compared with the case in which a conductive material having an average particle size in the order of micrometers is used. The average particle size can be measured by dynamic light scattering in which the conductive material is diluted in a good solvent for dispersion and can be expressed on a volume-averaged basis. In the measurement, Nanotrac UPA-150 manufactured by Microtrac, Inc. can be used.

The conductive material content in the fluid used in the present invention is preferably in the range of 5 mass % to 90 mass %, and more preferably 10 mass % to 60 mass % relative to the total amount of the fluid.

The fluid preferably contains a solvent to, for example, smooth application thereof. The solvent can be an organic solvent or an aqueous medium.

Examples of the solvent include aqueous media, such as distilled water, ion exchanged water, pure water, and ultrapure water, and organic solvents such as alcohols, ethers, esters, and ketones.

Examples of the alcohols include methanol, ethanol, n-propanol, isopropyl alcohol, n-butanol, isobutyl alcohol, sec-butanol, tert-butanol, heptanol, hexanol, octanol, nonanol, decanol, undecanol, dodecanol, tridecanol, tetradecanol, pentadecanol, stearyl alcohol, allyl alcohol, cyclohexanol, terpineol, terpineol, dihydroterpineol, ethylene glycol monomethyl ether, ethylene glycol monoethyl ether, ethylene glycol monobutyl ether, diethylene glycol monoethyl ether, diethylene glycol monomethyl ether, diethylene glycol monobutyl ether, tetraethylene glycol monobutyl ether, propylene glycol monomethyl ether, dipropylene glycol monomethyl ether, tripropylene glycol monomethyl ether, propylene glycol monopropyl ether, dipropylene glycol monopropyl ether, propylene glycol monobutyl ether, dipropylene glycol monobutyl ether, and tripropylene glycol monobutyl ether.

The fluid may optionally contain, in addition to the conductive material and the solvent, ethylene glycol, diethylene glycol, 1,3-butanediol, or isoprene glycol.

The fluid can be a liquid or viscous liquid of which the viscosity measured at 25° C. with a Brookfield type viscometer is from 0.1 mPa·s to 500,000 mPa·s, and preferably 0.5 mPa·s to 10,000 mPa·s. In the case where the fluid is applied by the above-mentioned technique such as ink-jet printing or reverse printing with a letterpress (printing is carried out), the viscosity is preferably in the range of approximately 5 mPa·s to 20 mPa·s.

In order to further enhance the adhesion between the support layer (I) and the conductive layer (II) which are included in the laminate of the present invention, the primer layer (X) can be formed between the support layer (I) and the conductive layer (II).

The primer layer (X) can be formed by applying primer to part or the whole of the surface of the support and then removing a solvent, such as an aqueous medium or an organic solvent, contained in the primer.

Examples of a technique for applying the primer to the surface of the support include a gravure process, a coating process, a screen process, a roller process, a rotary process, and a spray process.

In order to further enhance the adhesion to the support layer (II), the primer layer (X) may be subjected to surface treatment such as a plasma discharge treatment (e.g., a corona discharge treatment); a dry treatment (e.g., an ultraviolet treatment); or a wet treatment with water, an acid or alkaline solution, or an organic solution.

After the application of the primer to the surface of the support, the solvent contained in the coating layer is removed normally by, for example, drying the coating layer with a dryer to volatilize the solvent. The coating layer can be dried in any temperature range in which the solvent can be volatilized and in which the support is not impaired.

The amount of the primer to be applied to the surface of the support is preferably in the range of 0.01 g to 60 g per square meter of the support in order to produce good adhesion and conductivity; the amount is more preferably from 0.1 g to 10 g per square meter of the support in view of the absorbability of the solvent contained in the fluid and production costs.

A primer containing a variety of resins and solvents can be used for forming the primer layer (X).

Examples of usable resins include a urethane resin, a vinyl resin, a urethane-vinyl composite resin, an epoxy resin, an imide resin, an amide resin, a melamine resin, a phenol resin, polyvinyl alcohol, and polyvinylpyrrolidone.

Among these resins, a urethane resin, a vinyl resin, or a urethane-vinyl composite resin is preferably employed; at least one resin selected from the group consisting of a urethane resin having a polyether structure, a urethane resin having a polycarbonate structure, a urethane resin having a polyester structure, an acrylic resin, and a urethane-acrylic composite resin is more preferably employed; and a urethane-acrylic composite resin is further preferably employed to produce a laminate, such as a conductive pattern, which has a good adhesion and conductivity and which enables formation of a thin line.

The resin used in the primer is preferably a resin having a hydrophilic group in terms of a further enhancement in the adhesion to a variety of supports. Examples of the hydrophilic group include anionic groups, such as a carboxylate group and a sulfonate group, formed by partial or full neutralization with a basic compound; cationic groups; and nonionic groups; in particular, the anionic groups are preferred.

The resin may optionally have a crosslinkable functional group such as an alkoxysilyl group, a silanol group, a hydroxyl group, or an amino group. Accordingly, the primer layer (X) may have a crosslinked structure before the application of the fluid or may obtain a crosslinked structure after the application of the fluid, for example, through the firing.

A urethane-acrylic composite resin which can be used in the primer is preferably in the form of composite resin particles which are composed of a urethane resin and an acrylic polymer and which can be, for instance, dispersed in an aqueous medium.

Specific examples of the composite resin particles include materials in which resin particles of the above-mentioned urethane resins have covered part or the whole of the above-mentioned (meth)acrylic polymer. In this case, the (meth)acrylic polymer is preferably in the form of composite resin particles having a core-shell structure which is composed of the acrylic resin as the core layer and the urethane resin having a hydrophilic group as the shell layer. Especially in formation of a conductive pattern, such composite resin particles having a core-shell structure are preferably used because the composite resin particles eliminate use of a surfactant or another material which may reduce electrical properties. In the composite resin particles, it is preferred that the acrylic resin be substantially completely covered with the urethane resin; however, the acrylic resin is not necessarily completely covered, and part of the acrylic resin may be present at the outermost part of the composite resin particles provided that effects of the present invention are not impaired. The urethane resin may have a covalent bond to the acrylic resin but preferably has no covalent bond thereto.

The average particle size of the composite resin particles is preferably in the range of 5 nm to 100 nm in order to maintain good dispersion stability in water. The term “average particle size” herein refers to average particle size measured by dynamic light scattering on a volume-averaged basis as described in EXAMPLES later.

In the urethane-acrylic composite resin, the content proportion of the urethane resin to the acrylic resin (urethane resin/acrylic resin) is preferably in the range of 90/10 to 10/90, and more preferably 70/30 to 10/90.

A urethane resin usable in production of the urethane-acrylic composite resin can be a resin obtained by a reaction of a variety of polyols with polyisocyanate and optionally a chain extender.

Examples of the polyols include polyether polyols, polyester polyols, polyester ether polyols, and polycarbonate polyols.

Examples of the polyester polyols include aliphatic polyester polyols produced by esterification of a low-molecular-weight polyol with a polycarboxylic acid, aromatic polyester polyols, polyesters produced by ring-opening polymerization of a cyclic ester compound such as ε-caprolactone, and copolyesters thereof.

Examples of the low-molecular-weight polyol include ethylene glycol, propylene glycol, 1,6-hexanediol, and neopentyl glycol.

Examples of the polycarboxylic acid include aliphatic polycarboxylic acids such as succinic acid, adipic acid, sebacic acid, and dodecanedicarboxylic acid; aromatic polycaroboxylic acids such as terephthalic acid, isophthalic acid, and phthalic acid; and anhydrides and esters thereof.

Examples of the polyether polyols include polyether polyols produced by addition polymerization of alkylene oxide with an initiator that is at least one compound having two or more active hydrogen atoms.

Examples of the initiator include ethylene glycol, diethylene glycol, triethylene glycol, propylene glycol, trimethylene glycol, 1,3-butanediol, 1,4-butanediol, 1,6-hexanediol, neopentylglycol, glycerol, trimethylolethane, trimethylolpropane, bisphenol A, bisphenol F, bisphenol B, and bisphenol AD.

Examples of the alkylene oxide include ethylene oxide, propylene oxide, butylene oxide, styrene oxide, epichlorohydrin, and tetrahydrofuran.

Examples of the polyester ether polyols include polyester ether polyols obtained by a reaction of a polycarboxylic acid with a polyether polyol in which the alkylene oxide described above has been added to the above-mentioned initiator. The initiator and the alkylene oxide can be the same as the above-mentioned examples of the initiator and alkylene oxide that can be used in the production of the polyether polyols. The polycarboxylic acids can be the same as the above-mentioned examples of the polycarboxylic acid that can be used in the production of the polyester polyols.

Examples of the polycarbonate polyols include polycarbonate polyols obtained by a reaction of a carbonic acid ester with a polyol and polycarbonate polyols obtained by a reaction of phosgene with bisphenol A or another material.

Examples of the carbonic acid ester include methyl carbonate, dimethyl carbonate, ethyl carbonate, diethyl carbonate, cyclocarbonate, and diphenyl carbonate.

Examples of the polyol that can react with the carbonic acid ester include dihydroxy compounds having a relatively low molecular weight, such as ethylene glycol, diethylene glycol, triethylene glycol, 1,2-propylene glycol, 1,3-propylene glycol, dipropylene glycol, 1,4-butanediol, 1,3-butanediol, 1,2-butanediol, 2,3-butanediol, 1,5-pentanediol, 1,5-hexanediol, 2,5-hexanediol, 1,6-hexanediol, 1,7-heptanediol, 1,8-octanediol, 1,9-nonanediol, 1,10-decanediol, 1,11-undecanediol, 1,12-dodecanediol, 3-methyl-1,5-pentanediol, 2-ethyl-1,3-hexanediol, 2-methyl-1,3-propanediol, 2-methyl-1,8-octanediol, 2-butyl-2-ethylpropanediol, 2-methyl-1,8-octanediol, neopentyl glycol, 1,4-cyclohexanediol, 1,4-cyclohexanedimethanol, hydroquinone, resorcinol, bisphenol A, bisphenol F, and 4,4′-biphenol; polyether polyols such as polyethylene glycol, polypropylene glycol, and polytetramethylene glycol; and polyester polyols such as polyhexamethylene adipate, polyhexamethylene succinate, and polycaprolactone.

In view of introduction of a hydrophilic group into a urethane resin, examples of materials usable as the polyol include 2,2-dimethylolpropionic acid, 2,2-dimethylolbutanoic acid, 5-sulfoisophthalic acid, sulfoterephthalic acid, 4-sulfophthalic acid, and 5[4-sulfophenoxy]isophthalic acid.

Examples of the polyisocyanate include polyisocyanates having an aromatic structure, such as 4,4′-diphenylmethane diisocyanate, 2,4′-diphenylmethane diisocyanate, and tolylene diisocyanate; aliphatic polyisocyanates such as hexamethylene diisocyanate, cyclohexane diisocyanate, isophorone diisocyanate, dicyclohexylmethane diisocyanate, xylylene diisocyanate, and tetramethylxylylene diisocyanate; and polyisocyanates having an alicyclic structure. Among these, polyisocyanates having an alicyclic structure are preferably employed.

Examples of the chain extender include known materials such as ethylenediamine, piperazine, and isophorondiamine.

Acrylic resins which can be used for producing the urethane-acrylic composite resin can be acrylic resins produced by polymerization of a variety of (meth)acrylic monomers such as methyl (meth)acrylate.

Examples of the (meth)acrylic monomers include alkyl (meth)acrylates such as methyl (meth)acrylate, ethyl (meth)acrylate, n-butyl (meth)acrylate, i-butyl (meth) acrylate, t-butyl (meth) acrylate, 2-ethylhexyl (meth)acrylate, hexyl (meth)acrylate, and cyclohexyl (meth) acrylate.

Among these, methyl methacrylate enables printing of a thin line having a width ranging from approximately 0.01 μm to 200 μm, preferably approximately 0.01 μm to 150 μm, without the occurrence of bleeding (enables formation of a thin line), the width being needed to form a conductive pattern of, for example, an electric circuit. Hence, methyl methacrylate is preferably employed.

In addition to the methyl methacrylate, an alkyl (meth)acrylate containing an alkyl group having 2 to 12 carbon atoms is preferably used, an alkyl acrylate containing an alkyl group having 3 to 8 carbon atoms is more preferably used, and n-butyl acrylate is further preferably used in order to produce a printed matter with high print quality. In particular; use of such a material is preferred because it enables formation of a thin line of a conductive pattern without the occurrence of bleeding or another problem even in the case where a conductive ink is used.

The (meth)acrylic monomer can be a (meth)acrylic monomer having a crosslinkable functional group in order to further enhance, for instance, adhesion by introducing the crosslinkable functional group such as at least one amide group selected from the group consisting of a methylolamide group and an alkoxymethyl amide group to the acrylic resin.

The (meth)acrylic monomer having a crosslinkable functional group is preferably N-n-butoxymethyl (meth)acrylamide or N-isobutoxymethyl (meth)acrylamide in order to produce a laminate, such as a conductive pattern, which has an excellent adhesion and which enables formation of a thin line.

The urethane-acrylic composite resin can be produced through, for example, the following processes; the above-mentioned polyol is allowed to react with the polyisocyanate and optionally the chain extender, the product is dispersed in water to prepare a water dispersion of a urethane resin, and the (meth)acrylic monomer is polymerized in the water dispersion to produce an acrylic resin.

In particular, the polyisocyanate is allowed to react with the polyol in the absence of a solvent or in the presence of an organic solvent or a reactive diluent, such as a (meth)acrylic monomer, to produce a urethane resin; some or all the hydrophilic groups of the urethane resin are optionally neutralized with a basic compound or another material; the resulting product is optionally further allowed to react with a chain extender; and the resulting product is dispersed in an aqueous medium to produce a water dispersion of the urethane resin.

Then, the (meth)acrylic monomer is added to the water dispersion of the urethane resin and radically polymerized inside the urethane resin particles to produce an acrylic resin. In the case where the urethane resin is produced in the presence of the (meth)acrylic monomer, a polymerization initiator or another material is added after the production of the urethane resin to radically polymerize the (meth)acrylic monomer, thereby producing an acrylic resin.

Through these processes, a primer in which composite resin particles in which part or the whole of the acrylic resin is present inside the urethane resin particles have been dispersed in an aqueous medium can be produced.

A urethane resin usable in the primer, such as a urethane resin having a polyether structure, a urethane resin having a polycarbonate structure, or a urethane resin having a polyester structure, can be a urethane resin which is produced by a reaction of a polyol, such as the polyol described for the urethane-acrylic composite resin or a known polycarbonate polyol, with the above-mentioned polyisocyanate and chain extender. In this case, the polyol can be appropriately selected from the polyether polyols, known polycarbonate polyols, and aliphatic polyester polyols to produce the urethane resin having a predetermined structure.

The acrylic resin usable in the primer can be an acrylic resin produced by polymerization of the (meth)acrylic monomer described for the urethane-acrylic composite resin.

In the primer, the resin content relative to the total amount of the primer is preferably in the range of 10 mass % to 70 mass % to maintain, for example, easy application thereof, and more preferably 10 mass % to 50 mass %.

The solvent usable in the primer can be a variety of organic solvents or aqueous media.

Examples of the organic solvent include toluene, ethyl acetate, and methyl ethyl ketone. Examples of the aqueous media include water, organic solvents miscible with water, and mixtures thereof.

Examples of the organic solvents miscible with water include alcohols such as methanol, ethanol, n-propanol, isopropanol, ethyl carbitol, ethylcellosolve, and butyl cellosolve; ketones such as acetone and methyl ethyl ketone; polyalkylene glycols such as ethylene glycol, diethylene glycol, and propylene glycol; alkyl ethers of polyalkylene glycols; and lactams such as N-methyl-2-pyrrolidone.

In the primer, the solvent content relative to the total amount of the primer is preferably in the range of 25 mass % to 85 mass % to maintain easy application thereof, and more preferably 45 mass % to 85 mass %.

The primer appropriately contains known materials such as a crosslinking agent, a pH adjuster, a film-forming aid, a leveling agent, a thickener, a water-repellent agent, and a defoaming agent if needed.

The crosslinking agent enables formation of the primer layer (X) in which a crosslinked structure has been already formed before the application of the fluid or in which a crosslinked structure can be formed by, for example, heat in the firing after the application of the fluid.

Examples of the crosslinking agent include thermal crosslinking agents which can react at a relatively low temperature of approximately 25° C. or more and less than 100° C. to form a crosslinked structure, such as metal chelate compounds, polyamine compounds, aziridine compounds, basic metal compounds, and isocyanate compounds; thermal crosslinking agents which can react at a relatively high temperature of approximately 100° C. or more to form a crosslinked structure, such as at least one compound selected from the group consisting of melamine compounds, epoxy compounds, oxazoline compounds, carbodiimide compounds, and blocked isocyanate compounds; and a variety of photo-crosslinking agents.

The crosslinking agent content relative to the total resin content of 100 parts by mass in the primer is, depending on its type, generally preferably in the range of 0.01 mass % to 60 mass %, more preferably 0.1 mass % to 10 mass %, and further preferably 0.1 mass % to 5 mass % to form a conductive pattern having an excellent adhesion, conductivity, and durability.

Through the process [1] in which the support, the fluid containing the conductive material, and the primer are used, a base including the support layer (I), the conductive material-containing layer (II′), and the primer layer (X) optionally formed therebetween can be produced.

The process [2] will now be described.

In the process [2], the surface of the conductive material-containing layer (II′) which is to be in contact with the plating layer (III) is oxidized to form the conductive layer (II) having an oxidized surface, and this surface is plated to form the plating layer (III) on the oxidized surface of the conductive layer (II).

In particular, the process [2] involves a plasma discharge treatment, such as a corona treatment, to the surface of the layer (II′) included in the base formed in the process [1] and plating of the surface subjected to the plasma discharge treatment.

The plasma discharge treatment is not particularly limited; examples thereof include atmospheric pressure plasma discharge treatments, such as a corona discharge treatment, and vacuum plasma discharge treatments such as a glow discharge treatment and arc discharge treatment under vacuum or reduced pressure.

In the atmospheric pressure plasma discharge treatment, a plasma discharge treatment is carried out under an atmosphere in which the oxygen concentration is from approximately 0.1 mass % to 25 mass %. In the present invention, in order to produce excellent adhesion, the plasma discharge treatment is preferably a corona discharge treatment which is carried out preferably at an oxygen concentration ranging from 10 mass % to 22 mass %, and more preferably in the air (oxygen concentration of approximately 21 mass %).

The atmospheric pressure plasma discharge treatment is preferably carried out in a condition in which inert gas is used at the above-mentioned oxygen concentration, which eliminates formation of extraordinary irregularities in the surface of the conductive layer (II) with the result that adhesion can be further enhanced. Examples of the inert gas include an argon gas and a nitrogen gas.

In the atmospheric pressure plasma discharge treatment, for example, an atmospheric pressure plasma treatment system (AP-T01) manufactured by SEKISUI CHEMICAL CO., LTD. can be used.

In the atmospheric pressure plasma discharge treatment, gas such as air is preferably allowed to flow at a rate ranging from approximately 5 liters per minute to 50 liters per minute. The output is preferably in the range of approximately 50 W to 500 W. The time of the plasma treatment is preferably from approximately 1 second to 500 seconds.

In particular, the atmospheric pressure plasma discharge treatment is preferably the above-mentioned corona discharge treatment. In the case of performing the corona discharge treatment, for instance, corona surface modification test equipment (TEC-4AX) manufactured by KASUGA DENKI, Inc. can be used.

In the corona discharge treatment, the output is preferably in the range of approximately 5 W to 300 W. The time of the corona discharge treatment is preferably from approximately 0.5 seconds to 600 seconds.

The plasma discharge treatment such as the corona discharge treatment is preferably carried out under such conditions that irregularities are not formed in the surface of the conductive layer (II) by the treatment.

The plasma discharge treatment can be performed to the surface of the layer (II′) formed on the surface of the support layer (I); in particular, it is preferred that the plasma discharge treatment be performed to the surface of the layer (II′) formed on the surface of the primer layer (X) disposed on the surface of the support layer (I) in order to further enhance the adhesion between the individual layers.

Examples of a technique for plating the surface of the conductive layer (II) which has been oxidized through the above-mentioned treatment include wet plating such as electroless plating and electroplating, dry plating such as sputtering and vacuum deposition, and a combination of two or more thereof.

The plating layer (III) formed by such plating has a highly adhesion to the oxidized surface of the conductive layer (II). In particular, wet plating such as electroless plating or electroplating is preferably employed to produce a laminate having a further enhanced adhesion and conductivity, and electroplating is more preferably employed.

In electroless plating which can be employed for the plating, for example, the conductive material contained in the conductive layer (II), such as palladium or silver, is brought into contact with an electroless plating solution to precipitate metal contained in the electroless plating solution, such as copper, thereby forming an electroless plating layer (coating film) that is a metal coating film.

The electroless plating solution can be, for example, a solution containing a conductive material which is metal such as copper, nickel, chromium, cobalt, or tin; a reducing agent; and a solvent such as an aqueous medium or an organic solvent.

Examples of the reducing agent include dimethylaminoborane, hypophosphorous acid, sodium hypophosphite, dimethylamine borane, hydrazine, formaldehyde, sodium borohydride, and phenol.

The electroless plating solution can be a solution optionally containing any of complexing agents such as organic acids including monocarboxylic acids (e.g., acetic acid and formic acid), dicarboxylic acids (e.g., malonic acid, succinic acid, adipic acid, maleic acid, and fumaric acid), hydroxycarboxylic acids (e.g., malic acid, lactic acid, glycolic acid, gluconic acid, and citric acid), amino acids (e.g., glycine, alanine, iminodiacetic acid, arginine, aspartic acid, and glutamic acid), amino polycarboxylic acids (e.g., iminodiacetic acid, nitrilotriacetic acid, ethylenediaminediacetic acid, ethylenediaminetetraacetic acid, and diethylenetriaminepentaacetic acid); soluble salts (e.g., sodium salt, potassium salt, and ammonium salt) of these organic acids; and amines (e.g., ethylenediamine, diethylenetriamine, and triethylenetetramine).

The electroless plating solution is preferably used at a temperature ranging from approximately 20° C. to 98° C.

In electroplating which can be employed for the plating, for example, electricity is allowed to flow in a state in which an electroplating solution is in contact with a conducive material contained in the conductive layer (II) or the surface of an electroless plating layer (coating film) formed by the above-mentioned electroless plating, so that metal contained in the electroplating solution, such as copper, is precipitated on the cathode which is the conductive material contained in the conductive layer (II) or the surface of the electroless plating layer (coating film) formed by the above-mentioned electroless plating, thereby forming an electroplating layer (metal coating film).

The electroplating solution can be a solution containing, for instance, metal such as copper, nickel, chromium, cobalt, or tin; sulfide thereof; sulfuric acid; and an aqueous medium. In particular, the electroplating solution can be, for example, a solution containing copper sulfate, sulfuric acid, and an aqueous medium.

The electroplating solution is preferably used at a temperature ranging from approximately 20° C. to 98° C.

The electroplating eliminates use of a toxic substance and enables good workability; hence, it is preferred that a layer be formed of copper by the electroplating.

The dry plating can be sputtering or vacuum deposition. In the sputtering, inert gas (mainly argon gas) is introduced in vacuum, a negative ion is applied to a material for forming the plating layer (III) to generate glow discharge, the atoms of the inert gas are then ionized and allowed to collide with the surface of the material for forming the plating layer (III) at high speed to induce the ejection of the atoms and molecules of the material for forming the plating layer (III), and then the ejected atoms and molecules are allowed to swiftly adhere to the surface of the conductive layer (II), thereby forming the plating layer (III).

Examples of the material for forming the plating layer (III) include chromium (Cr), copper (Cu), titanium (Ti), silver (Ag), platinum (Pt), gold (Au), nickel-chromium (Ni—Cr), SUS, copper-zinc (Cu—Zn), ITO, SiO₂, TiO₂, Nb₂O₅, and ZnO.

In the case where the sputtering is employed for the plating, for instance, a magnetron sputtering apparatus can be used.

Through the process [2] described above, a laminate having the plating layer (III) can be produced.

The laminate produced through the above-mentioned processes can be used as a conductive pattern. Specifically, the laminate can be suitably used as conductive patterns for forming electronic circuits using, for example, silver ink; forming peripheral wiring used in organic solar cells, terminals for electronic books, organic EL devices, organic transistors, flexible printed wiring boards, and RFID; and producing wiring of electromagnetic interference shields used in plasma displays. More specifically, the laminate can be suitably used for forming circuit boards.

In the case where the laminate is used as a conductive pattern, the fluid for forming the conductive layer (II) can be applied to the position at which a predetermined pattern is to be formed, and then firing or another process is carried out to produce the conductive pattern having the intended shape.

The conductive pattern can be formed also by photolithographic etching such as a subtractive process, a semi-additive process, or a fully-additive process.

In the subtractive process, an etching resist layer having a shape corresponding to a predetermined pattern is formed on the plating layer (III) of the preliminarily produced laminate of the present invention, and then the parts of the plating layer (III) and conductive layer (II) at which the etching resist layer have not been formed are removed by being dissolved through development with a liquid agent, thereby forming the intended pattern. The liquid agent can be a liquid agent containing, for instance, copper chloride or iron chloride.

In the semi-additive process, the surface of the layer (II′) which is included in a base along with the support layer (I) is subjected to a plasma discharge treatment to form the layer (II), a plating resist layer having a shape corresponding to a predetermined pattern is formed on the oxidized surface of the conductive layer (II), the plating layer (III) is subsequently formed by electroplating or electroless plating, and then the plating resist layer and part of the conductive layer (II) contacting the plating resist layer are removed by being dissolved by, for example, a liquid agent, thereby forming the intended pattern.

In the fully-additive process, the primer layer (X) is formed on the support layer (I), the pattern of the layer (II′) is formed by ink-jet printing or reverse printing, the layer (II′) is subjected to a plasma discharge treatment to form the pattern of the layer (II), and then the plating layer (III) is formed on the oxidized surface of the conductive layer (II) by electroplating or electroless plating, thereby forming the intended pattern.

The conductive pattern produced through any of the above-mentioned processes has a significantly high durability which enables good flow of electricity to be maintained without the occurrence of peeling of the layers or another problem and can be therefore suitably used in an application which particularly needs durability, such as producing electronic circuits using, for example, silver ink and circuit-forming substrates used in, for instance, integral circuits; forming peripheral wiring used in organic solar cells, terminals for electronic books, organic EL devices, organic transistors, flexible printed wiring boards, and RFID; and forming wiring of electromagnetic interference shields used in plasma displays. In particular, the conductive pattern subjected to the plating enables formation of a highly reliable wiring pattern which can maintain good flow of electricity for a long time without the occurrence of disconnection or another problem; hence, the conductive pattern can be, for example, used in an application generally called copper clad laminate (CCL) for a flexible printed circuit (FPC), tape automated bonding (TAB), chip on film (COF), and a printed wring board (PWB).

### EXAMPLES

The present invention will now be described in detail with reference to Examples.

[Preparation of Primer (X-1)]

Inside a container having a thermometer, a nitrogen gas introduction tube, and a stirrer and purged with nitrogen, 100 parts by mass of a polyester polyol (polyester polyol produced by a reaction of 1,4-cyclohexanedimethanol with neopentylglycol and adipic acid), 17.6 parts by mass of 2,2-dimethylolpropionic acid, 21.7 parts by mass of 1,4-cyclohexanedimethanol, and 106.2 parts by mass of dicyclohexylmethane diisocyanate were allowed to react with each other in 178 parts by mass of methyl ethyl ketone to produce an organic solvent solution of a urethane prepolymer having isocyanate groups on its terminals.

Then, 13.3 parts by mass of triethylamine was added to the organic solvent solution of the urethane resin to neutralize some or all of the carboxyl groups contained in the urethane resin. Then, 380 parts by mass of water was added thereto, and the product was thoroughly stirred to produce an aqueous dispersion of the urethane resin.

Then, 8.8 parts by mass of an aqueous solution of 25 mass % ethylenediamine was added to the aqueous dispersion, and the product was stirred to extend the chain of a polyurethane resin that was in the form of particles. The resulting product was subsequently subjected to aging and removal of the solvent to produce an aqueous dispersion of a urethane resin (x-1) with a solid content concentration of 30 mass %. The urethane resin (x-1) had a weight average molecular weight of 53,000.

Into a reaction vessel having a stirrer, a reflux condenser tube, a nitrogen introduction tube, a thermometer, a dropping funnel for dropping a monomer mixture, and a dropping funnel for dropping a polymerization catalyst, 140 parts by mass of deionized water and 100 parts by mass of the aqueous dispersion of the urethane resin (x-1), which had been obtained as described above, were put, and the temperature was increased to 80° C. under blowing of nitrogen.

Into the reaction vessel at 80° C., a monomer mixture of 60 parts by mass of methyl methacrylate, 30 parts by mass of n-butyl acrylate, and 10 parts by mass of N-n-butoxymethylacrylamide and 20 parts by mass of an aqueous solution of ammonium persulfate (concentration of 0.5 mass %) were separately dropped with the different dropping funnels over 120 minutes under stirring to induce polymerization while the temperature inside the reaction vessel was maintained at 80±2° C.

After the dropping, the resulting product was stirred for 60 minutes at the same temperature to produce an aqueous dispersion of a urethane-acrylic composite resin having the shell layer of the urethane resin (x-1) and the core layer of a vinyl polymer.

The temperature inside the reaction vessel was decreased to 40° C., deionized water was subsequently used to adjust the nonvolatile content to be 20.0 mass %, and then the aqueous dispersion was filtered through a filter cloth of 200 mesh, thereby producing a primer (X-1).

[Preparation of Primer (X-2)]

Into a four-neck flask having a cooling pipe, a stirrer, a thermometer, and a nitrogen introduction tube, a vinyl monomer mixture containing 45 parts by mass of methyl methacrylate, 45 parts by mass of n-butyl acrylate, 5 parts by mass of 4-hydroxybutyl acrylate, and 5 parts by mass of methacrylic acid and ethyl acetate were put. The content was heated to 50° C. under stirring in a nitrogen atmosphere, and then 2.0 parts by mass of 2,2′-azobis(2-methylbutyronitrile) was put into the flask and allowed to react with the content for 24 hours to produce 500 parts by mass (nonvolatile content of 20 mass %) of a mixture containing the ethyl acetate and a vinyl polymer having a weight average molecular weight of 400000.

Then, 500 parts by mass of the mixture and 22.5 parts by mass of a crosslinking agent composition 1 (nonvolatile content: 20 mass %) containing ethyl acetate and a crosslinking agent 1 that was an isocyanurate of hexamethylene diisocyanate were mixed with each other to produce a primer (X-2) having a nonvolatile content of 20 mass %.

[Preparation of Conductive Ink]

Silver particles having an average particle size of 30 nm were dispersed in a mixed solvent containing 45 parts by mass of ethylene glycol and 55 parts by mass of ion exchanged water to prepare a conductive ink 1.

The viscosity of the conductive ink 1 was adjusted to be 10 mPa·s with ion exchanged water and a surfactant to prepare a conductive ink 2 for ink-jet printing.

### Example 1

To the surface of a support that was a polyimide film (Kapton200H manufactured by DU PONT-TORAY CO., LTD., thickness: 50 μm), the primer (X-1) was applied with a spin coater such that the thickness would be 0.1 μm after drying. Then, the product was dried with a hot air dryer at 80° C. for 5 minutes to form a primer layer on the surface of the support.

The conductive ink 1 was applied to the surface of the primer layer by spin coating and then fired at 250° C. for 3 minutes to produce a base having a silver-containing layer (thickness: 0.1 μm) corresponding to the layer (II′). The surface resistance of the layer corresponding to the layer (II′) was measured by a technique described later and was 2 Ω/□.

Then, the surface of the layer corresponding to the layer (II′) was subjected to a corona discharge treatment with AP-T01 (atmospheric pressure plasma treatment system manufactured by SEKISUI CHEMICAL CO., LTD., gas: air (oxygen concentration of approximately 21 mass %), flow rate: 20 liter/minute, output: 150 W, and processing time: 5 seconds) to form a conductive layer in which the surface of the silver-containing layer had been oxidized. The surface resistance of the conductive layer was measured and was 4Ω/□; the surface resistance was larger than that of the layer before the corona discharge treatment, which showed that the surface had been oxidized. The surface was analyzed with an X-ray photoelectron spectrometer (ESCA3400 manufactured by SHIMADZU CORPORATION); in the analysis, the peak showing the oxidation of silver was able to be observed. An increase in the surface resistance due to the oxidation was confirmed.

Then, electroplating in which the cathode and the anode were the oxidized surface of the conductive layer and phosphorus-containing copper, respectively, was carried out for 15 minutes at a current density of 2 A/dm² with an electroplating solution containing copper sulfate to form a copper plating layer having a thickness of 8 μm on the oxidized surface of the conductive layer. The electroplating solution contained 70 g/liter of copper sulfate, 200 g/liter of sulfuric acid, 50 mg/liter of chlorine ions, and 5 g/liter of Top Lucina SF (brightener manufactured by Okuno Chemical Industries Co., Ltd.).

Through these processes, a laminate (L-1) having a layered structure including the layers corresponding to the support layer (I), the primer layer (X), the conductive layer (II), and the plating layer (III) was produced.

### Example 2

Instead of the corona discharge treatment with AP-T01 (atmospheric pressure plasma treatment system manufactured by SEKISUI CHEMICAL CO., LTD), a corona discharge treatment was carried out with TEC-4AX (corona surface modification test equipment manufactured by KASUGA DENKI, Inc., gas: air (oxygen concentration of approximately 21 mass %), gap: 1.5 mm, output: 100 W, and processing time: 2 seconds). Except for this change, a laminate (L-2) having a layered structure including layers corresponding to the support layer (I), the primer layer (X), the conductive layer (II), and the plating layer (III) was produced as in Example 1. The surface resistance of the layer corresponding to the layer (II′) was 3Ω/□ before the corona discharge treatment while the surface resistance of the conductive layer formed by the corona discharge treatment was 5Ω/□, which showed an increase in the surface resistance. The surface was analyzed with the X-ray photoelectron spectrometer in the manner described above; in the analysis, the peak showing the oxidation of silver was able to be observed. An increase in the surface resistance due to the oxidation was confirmed.

### Example 3

To the surface of a support that was a polyimide film (Kapton200H manufactured by DU PONT-TORAY CO., LTD.), the primer (X-1) was applied with a spin coater such that the thickness would be 0.1 μm after drying. Then, the product was dried with a hot air dryer at 80° C. for 5 minutes to form a primer layer on the surface of the support.

Then, the conductive ink 2 was applied to the surface of the primer layer in the form of a straight line having a thickness of 0.5 μm, a width of 100 μm, and a length of 3 cm with an ink-jet printer (ink-jet tester EB100 manufactured by Konica Minolta IJ Technologies, Inc., evaluative printer head KM512L, and rate of ejection: 42 pl). The product was subsequently dried at 150° C. for an hour to produce a base having a silver-containing layer corresponding to the layer (II′) (after the drying, the thickness was 0.1 μm, the width was 1 mm, and the length was 1 cm). The surface resistance of the layer corresponding to the layer (II′) was 2Ω/□.

The surface of the layer corresponding to the layer (II′) was subjected to a corona discharge treatment with TEC-4AX (corona surface modification test equipment manufactured by KASUGA DENKI, Inc., gas: air (oxygen concentration of approximately 21 mass %), gap: 1.5 mm, output: 100 W, and processing time: 2 seconds) to form a conductive layer in which the surface of the layer corresponding to the layer (II′) had been oxidized. The surface resistance of the layer corresponding to the layer (II′) was 2Ω/□ before the corona discharge treatment while the surface resistance of the conductive layer formed by the corona discharge treatment was 3Ω/□, which showed an increase in the surface resistance. The surface was analyzed with the X-ray photoelectron spectrometer in the manner described above; in the analysis, the peak showing the oxidation of silver was able to be observed. An increase in the surface resistance due to the oxidation was confirmed.

Then, electroplating in which the cathode and the anode were the oxidized surface of the conductive layer and phosphorus-containing copper, respectively, was carried out for 15 minutes at a current density of 2 A/dm² with an electroplating solution containing copper sulfate to form a copper plating layer having a thickness of 8 μm on the surface of the layer formed by the plasma discharge treatment. The electroplating solution contained 70 g/liter of copper sulfate, 200 g/liter of sulfuric acid, 50 mg/liter of chlorine ions, and 5 g/liter of Top Lucina SF (brightener manufactured by Okuno Chemical Industries Co., Ltd.).

Through these processes, a laminate (L-3) having a layered structure including the layers corresponding to the support layer (I), the primer layer (X), the conductive layer (II), and the plating layer (III) was produced.

### Example 4

Except that the following electroless plating was carried out in place of the electroplating, a laminate (L-4) having a layered structure including layers corresponding to the support layer (I), the primer layer (X), the conductive layer (II), and the plating layer (III) was produced as in Example 2. The surface resistance of the layer corresponding to the layer (II′) was 2Ω/□ before the corona discharge treatment while the surface resistance of the conductive layer formed by the corona discharge treatment was 3Ω/□, which showed an increase in the surface resistance. The surface was analyzed with the X-ray photoelectron spectrometer in the manner described above; in the analysis, the peak showing the oxidation of silver was able to be observed. An increase in the surface resistance due to the oxidation was confirmed.

In the electroless plating, the layer formed by the corona discharge treatment was immersed into a catalyst bath (OPC-SALWOPC-80 manufactured by Okuno Chemical Industries Co., Ltd.) for five minutes and then washed with water. The resulting layer was subsequently immersed into an accelerator bath at 25° C. (OPC-555 manufactured by Okuno Chemical Industries Co., Ltd.) for five minutes and washed with water. Then, the product was immersed into an electroless copper plating bath at 30° C. (ATS Addcopper manufactured by Okuno Chemical Industries Co., Ltd.) such that the plating layer would have a thickness of 8 μm, and then the resulting product was washed with water.

### Example 5

A support that was a polyimide film (Kapton200H manufactured by DU PONT-TORAY CO., LTD.) was immersed into an aqueous solution of 1 mol/L potassium hydroxide at 40° C. for 15 minutes, thoroughly washed with ion exchanged water, and dried at normal temperature.

Then, the conductive ink 1 was applied to the surface of the dried polyimide film by spin coating and subsequently fired at 250° C. for 3 minutes to produce a base having a silver-containing layer (thickness: 0.1 μm) corresponding to the layer (II′).

The surface of the silver-containing layer was subjected to a corona discharge treatment with TEC-4AX (corona surface modification test equipment manufactured by KASUGA DENKI, Inc., gas: air (oxygen concentration of approximately 21 mass %), gap: 1.5 mm, output: 100 W, and processing time: 2 seconds). The surface resistance of the layer corresponding to the layer (II′) was 2Ω/□ before the corona discharge treatment while the surface resistance of the conductive layer formed by the corona discharge treatment was 3Ω/□, which showed an increase in the surface resistance. The surface was analyzed with the X-ray photoelectron spectrometer in the manner described above; in the analysis, the peak showing the oxidation of silver was able to be observed.

Then, electroplating in which the cathode and the anode were the oxidized surface of the conductive layer and phosphorus-containing copper, respectively, was carried out for 15 minutes at a current density of 2 A/dm² with an electroplating solution containing copper sulfate to form a copper plating layer having a thickness of 8 μm on the oxidized surface of the conductive layer. The electroplating solution contained 70 g/liter of copper sulfate, 200 g/liter of sulfuric acid, 50 mg/liter of chlorine ions, and 5 g/liter of Top Lucina SF (brightener manufactured by Okuno Chemical Industries Co., Ltd.).

Through these processes, a laminate (L-5) having a layered structure including the layers corresponding to the support layer (I), the conductive layer (II), and the plating layer (III) was produced.

### Example 6

Except that the primer (X-2) was used in place of the primer (X-1), a laminate (L-6) having a layered structure including layers corresponding to the support layer (I), the conductive layer (II), and the plating layer (III) was produced as in Example 2. The surface resistance of the layer corresponding to the layer (II′) was 2Ω/□ before the corona discharge treatment while the surface resistance of the conductive layer formed by the corona discharge treatment was 3Ω/□, which showed an increase in the surface resistance. The surface was analyzed with the X-ray photoelectron spectrometer in the manner described above; in the analysis, the peak showing the oxidation of silver was able to be observed. An increase in the surface resistance due to the oxidation was confirmed.

### Comparative Example 1

Except that the plasma discharge treatment and the corona discharge treatment were not carried out, a laminate (L′-1) having a layered structure including layers corresponding to the support layer (I), the primer layer (X), the layer (II′), and the plating layer (III) was produced as in Example 3. The surface resistance of the layer corresponding to the layer (II′) was 2Ω/□, and the surface resistance of the layer corresponding to the layer (II′) before the plating process was also 2Ω/□; the surface resistance remained the same. The surface was analyzed with the X-ray photoelectron spectrometer in the manner described above; in the analysis, the peak showing the oxidation of silver was not able to be observed. An increase in the surface resistance was not confirmed.

### Comparative Example 2

Instead of the plasma discharge treatment and the corona discharge treatment, the surface of the layer corresponding to the layer (II′) was irradiated with ultraviolet light with ultraviolet surface treatment equipment (low pressure mercury lamp EUV200WS manufactured by Senengineering Co., Ltd., illuminance: 20 mW/cm2, output: 200 W, and irradiation time: 60 seconds). Except for this change, a laminate (L′-2) having a layered structure including layers corresponding to the support layer (I), the primer layer (X), the layer irradiated with ultraviolet light, and the plating layer (III) was produced as in Example 1. The surface resistance of the layer corresponding to the layer (II′) was 2Ω/□ before the irradiation with ultraviolet light, and the surface resistance of the layer irradiated with ultraviolet light was also 2Ω/□; the surface resistance remained the same. The surface was analyzed with the X-ray photoelectron spectrometer in the manner described above; in the analysis, the peak showing the oxidation of silver was not able to be observed. An increase in the surface resistance was not confirmed.

[Measurement of Surface Resistance]

The surface resistance was measured at arbitrary ten points of a surface with the in-line four-point probe (ASP) of Loresta GP (model MCP-T610) manufactured by DIA Instruments Co., Ltd., and the average of the obtained surface resistance values were calculated.

[Evaluation of Adhesion]

<Visual Evaluation>

An adhesive cellophane tape (CT405AP-24 manufactured by Nichiban Co., Ltd., 24 mm) was attached to the surface of the plating layer of each of the laminates by being pressed with a finger, and then the adhesive cellophane tape was removed in a direction of 90 degrees with respect to the surface of the plating layer included in the laminate. The adhesive surface of the removed adhesive cellophane tape was visually observed to confirm the presence or absence of peeling of a layer and the interface at which the peeling had occurred.

<Evaluation by Peeling Test>

Measurement of peel strength was carried out in accordance with IPC-TM-650 NUMBER 2.4.9. In the measurement, the lead width was 1 mm, and the peeling angle was 90°. The peel strength tends to be increased in response to an increase in the thickness of a plating layer; in the present invention, the measurement of peel strength was carried out on the basis of commonly employed measurement made to an 8-μm-thick plating layer.

TABLE 1

| | | Example 1 | Example 2 | Example 3 | Example 4 |
|---|---|---|---|---|---|
| Structure of | Layer (I) | Polyimide | Polyimide | Polyimide | Polyimide |
| Laminate | Primer Layer (X) | Primer (X-1) | Primer (X-1) | Primer (X-1) | Primer (X-1) |
| | Application of Conductive | Spin Coating | Spin Coating | Ink-Jet Printing | Spin Coating |
| | Ink for Forming Layer (II) | | | | |
| | Surface Resistance of | 2 | 3 | 2 | 2 |
| | Conductive Layer before | | | | |
| | Surface Treatment (Ω/□) | | | | |
| | Surface Treatment | Plasma | Corona | Corona | Corona |
| | | Discharge | Discharge | Discharge | Discharge |
| | | Treatment with | Treatment with | Treatment with | Treatment with |
| | | AP-T01 | TEC-4AX | TEC-4AX | TEC-4AX |
| | Surface Resistance of | 4 | 5 | 3 | 3 |
| | Oxidized Surface of | | | | |
| | Conductive Layer (II) (Ω/□) | | | | |
| | Plating Layer (III) | Electroplating | Electroplating | Electroplating | Electroless |
| | | | | | Plating |
| Adhesion | Visual Evaluation | No Peeling | No Peeling | No Peeling | No Peeling |
| | Peel Strength N/m | 490 | 620 | 540 | 510 |

TABLE 2

| | | | | Comparative | Comparative |
|---|---|---|---|---|---|
| | | Example 5 | Example 6 | Example 1 | Example 2 |
| Structure of | Layer (I) | Polyimide | Polyimide | Polyimide | Polyimide |
| Laminate | Primer Layer (X) | None | Primer (X-2) | Primer (X-1) | Primer (X-1) |
| | Application of Conductive Ink | Spin Coating | Spin Coating | Ink-Jet Printing | Spin Coating |
| | Surface Resistance of | 2 | 2 | 2 | 2 |
| | Conductive Layer before | | | | |
| | Surface Treatment (Ω/□) | | | | |
| | Surface Treatment | Corona | Corona | None | Ultraviolet Light |
| | | Discharge | Discharge | | Radiation |
| | | Treatment with | Treatment with | | |
| | | TEC-4AX | TEC-4AX | | |
| | Surface Resistance of | 3 | 3 | 2 | 2 |
| | Oxidized Surface of | | | | |
| | Conductive Layer (II) (Ω/□) | | | | |
| | Plating Layer (III) | Electroplating | Electroplating | Electroplating | Electroplating |
| Adhesion | Visual Evaluation | Peeling at | Slight Partial | Partial Peeling | Partial Peeling |
| | | Interface | Peeling at | at Interface | at Interface |
| | | between | Interface | between | between |
| | | Polyimide and | between Primer | Conductive | Conductive |
| | | Conductive | Resin Layer | Layer and | Layer and |
| | | Layer | and Layer (II) | Plating Layer | Plating Layer |
| | Peel Strength N/m | 300 | 450 | 5 | 15 |

In Tables 1 and 2, the term “AP-T01” refers to an atmospheric pressure plasma treatment system manufactured by SEKISUI CHEMICAL CO., LTD. The term “TEC-4AX” refers to corona surface modification test equipment manufactured by KASUGA DENKI, Inc.

The laminate of each of Examples 1 to 4 in which the surface of the conductive layer formed using the conductive ink had been oxidized and in which the plating layer had been formed on the oxidized surface had an excellent adhesion. The laminate of Example 5 in which a primer layer had not been formed had an excellent adhesion between the conductive layer and the plating layer; however, peeling occurred at the interface between the polyimide film and the conductive layer. In the laminate of Example 6 in which the primer (X-2) had been used as primer, slight peeling occurred at part of the interface between the primer layer and the conductive layer.

In the laminate of Comparative Example 1 in which the surface of the conductive layer had not been oxidized and in which the plating layer had been formed on this surface, peeling occurred at part of the interface between the conductive layer and the plating layer. In the laminate of Comparative Example 2 in which the surface of the conductive layer had been irradiated with ultraviolet light and in which the plating layer had been formed on this surface, peeling occurred at the interface between the conductive layer and the peeling layer.

1. A laminate comprising a support layer (I), a conductive layer (II), and a plating layer (III), wherein the conductive layer (II) has an oxidized surface, and the plating layer (III) is disposed on the oxidized surface of the conductive layer (II).

2. The laminate according to claim 1, wherein part or the whole of the oxidized surface of the conductive layer (II) contains silver oxide.

3. The laminate according to claim 1, further comprising a primer layer (X) interposed between the support layer (I) and the conductive layer (II).

4. The laminate according to claim 1, wherein the plating layer (III) is a layer formed by electroplating the oxidized surface of the conductive layer (II).

5. The laminate according to claim 1, wherein the resistance of the oxidized surface of the conductive layer (II) is in the range of 0.1Ω/□ to 50Ω/□.

6. A conductive pattern comprising the laminate according to claim 1.

7. An electric circuit comprising the laminate according to claim 1.

8. A method for producing a laminate, the method comprising:
preparing a base including a support layer (I), a layer (II′) containing a conductive material, and a primer layer (X) interposed between the support layer (I) and the layer (II′);
performing a corona discharge treatment to the surface of the layer (II′) of the base to form a conductive layer (II) having an oxidized surface; and
electroplating the oxidized surface of the conductive layer (II) to form a plating layer (III) on the oxidized surface of the conductive layer (II).
